(19) United States
(12) Patent Application Publication
(10) Pub. No.: US 2018/0082674 A1
(43) Pub. Date: Mar. 22, 2018

(54) ULTRASONIC SENSOR ARRAY ASSEMBLY

(71) Applicant: TYCO ELECTRONICS CORPORATION, Berwyn, PA (US)

(72) Inventors: David Bruce Sarraf, Elizabethtown, PA (US); Charles David Fry, New Bloomfield, PA (US); Michael F. Laub, Enola, PA (US)

(21) Appl. No.: 15/273,087

(22) Filed: Sep. 22, 2016

(51) Int. Cl. G10K 11/34; G01R 1/04

(52) U.S. Cl. CPC G10K 11/346; G01R 1/04

(57) ABSTRACT

An ultrasonic sensor array assembly includes a substrate having a plurality of contact pads, and a plurality of ultrasonic elements supported on the substrate. Each of the plurality of ultrasonic elements is independently electrically connected to a respective one of the plurality of contact pads. The plurality of ultrasonic elements are configured to emit an electrically phased ultrasonic beam.

### BACKGROUND OF THE DISCLOSURE

Embodiments of the present disclosure generally relate to ultrasonic sensor array assemblies.

Ultrasonic sensors are used in various applications to detect the presence of an object. For example, various vehicles include one or more ultrasonic sensors to detect the presence of an object, such as another vehicle, structure, individual, or the like. The ultrasonic sensors may be part of an array that is secured to a bumper of the vehicle, for example. The ultrasonic sensors provide presence information that may be analyzed by one or more processors to provide information to an operator regarding the immediate surroundings around the vehicle.

One known ultrasonic sensor array includes a plurality of individual ultrasonic transducers that form an ultrasonic beam pattern through phasing. In order to achieve phasing, the transducers are mechanically mounted on a stepped aluminum pedestal. The transducers are electrically connected in parallel to a single source or driver. As such, a single contiguous electrical connection connects all of the individual transducers to a driver.

The different levels of the transducer elements on the pedestal allows for the phasing to occur. However, the mechanical phasing of the transducer elements may not provide an efficient system and method for phasing. Further, the stepped pedestal may provide a bulky and obtrusive assembly.

A need exists for a system and method for electrically phasing ultrasonic transducer elements.

### BRIEF DESCRIPTION OF THE DISCLOSURE

Certain embodiments of the present disclosure provide an ultrasonic sensor array assembly that may include a substrate having a plurality of contact pads, and a plurality of ultrasonic elements supported on the substrate. The ultrasonic elements may be coplanar. Each of the ultrasonic elements is independently electrically connected to a respective one of the plurality of contact pads. The ultrasonic elements are configured to emit an electrically phased ultrasonic beam.

A cover may be positioned over the plurality of ultrasonic elements. Perimeter walls of the cover may bound the plurality of contact pads. Alternatively, the plurality of contact pads may bound the perimeter walls of the cover.

The ultrasonic sensor array assembly may also include a plurality of wires. Each of the ultrasonic elements connects to a respective one of the contact pads through a respective one of the wires. Each of the wires may include a contact segment that is spring-biased into a respective one of the ultrasonic elements. Each wire may include a bent spring beam portion.

At least portions of the wires may extend over internal or external wall portions of the cover. At least portions of the wires may be cradled within one or more channels formed through the cover.

In at least one embodiment, each of the wires includes a via-contacting portion retained within a via that is secured within the cover.

The cover may include one or more prismatic elements that are configured to shape the electrically phased ultrasonic beam that is emitted from the plurality of ultrasonic elements.

### BRIEF DESCRIPTION OF THE DRAWINGS

FIG. 1 illustrates a perspective top view of an ultrasonic sensor array assembly, according to an embodiment of the present disclosure.

FIG. 2 illustrates a perspective top view of an ultrasonic sensor array assembly, according to an embodiment of the present disclosure.

FIG. 3 illustrates a top view of a portion of an ultrasonic sensor array assembly, according to an embodiment of the present disclosure.

FIG. 4 illustrates a perspective top view of a substrate, according to an embodiment of the present disclosure.

FIG. 5 illustrates an axial view of a wire segment positioned on an internal wall portion of a cover, according to an embodiment of the present disclosure.

FIG. 6 illustrates a lateral view of a contact segment of a wire contacting an ultrasonic element, according to an embodiment of the present disclosure.

FIG. 7 illustrates a lateral view of a contact segment of a wire contacting an ultrasonic element, according to an embodiment of the present disclosure.

FIG. 8 illustrates a transverse cross-sectional view of wires secured to a portion of a cover, according to an embodiment of the present disclosure.

FIG. 9 illustrates a transverse cross-sectional view of a wire secured to a portion of a cover, according to an embodiment of the present disclosure.

FIG. 10 illustrates a transverse cross-sectional view of a cover, according to an embodiment of the present disclosure.

FIG. 11 illustrates a transverse cross-sectional view of a cover, according to an embodiment of the present disclosure.

FIG. 12 illustrates a transverse cross-sectional view of a cover, according to an embodiment of the present disclosure.

FIG. 13 illustrates a transverse cross-sectional view of a cover, according to an embodiment of the present disclosure.

### DETAILED DESCRIPTION OF THE DISCLOSURE

Embodiments of the present disclosure provide ultrasonic sensor array assemblies that may include a plurality of individual transducer or ultrasonic elements, each of which is independently electrically connected to a contact pad, which, in turn, may be electrically connected to an energy source that is configured to energize the ultrasonic elements. In at least one embodiment, each ultrasonic element is electrically connected to a contact pad, such as a wire bond pad, through a separate and distinct wire. The wire bond pad may be electrically connected to an electrical connecting member, such as a pin, that connects to a circuit board, for example, that is configured to emit an energizing signal into each of the ultrasonic elements. The energizing signals for each ultrasonic element may differ in time, thereby causing a composite waveform emitted from the assembly to deviate from planarity. Because each ultrasonic element is electrically independent from one another, the ultrasonic sensor array assembly is able to form an ultrasonic beam through electronic phasing.

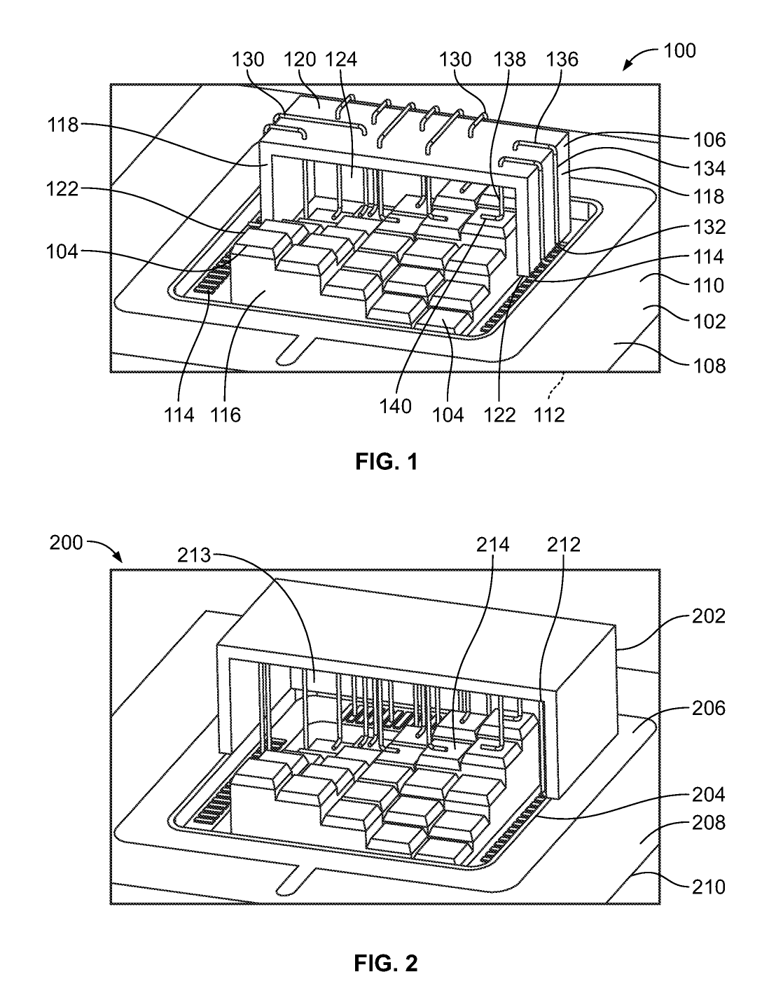

FIG. 1 illustrates a perspective top view of an ultrasonic sensor array assembly 100, according to an embodiment of the present disclosure. The assembly 100 may include a planar substrate 102 (which may be formed of ceramic, for example), an array of ultrasonic elements 104, and a cover 106 positioned over the array of transducer or ultrasonic elements 104. As shown in FIG. 1, the cover 106 is shown cut away to show the internal components of the assembly 100.

The substrate 102 may include a planar main body 108 having a support or top surface 110 integrally connected to an opposite or bottom surface 112. Conductive contact pads, such as wire bond pads 114 (which may be formed of a conductive metal), are secured to the substrate 102 and are exposed through the top surface 110. Each wire bond pad 114 may be electrically connected to a contact member (hidden from view), such as a conductive pin that extends from the bottom surface 112. The contact members may be connected to a circuit board, driver, or the like that is configured to emit energizing signals into the pins. The energizing signals pass from the pins into the wire bond pads 114.

Each ultrasonic element 104 may be formed of a piezoelectric and/or piezo-restrictive material. For example, each ultrasonic element 104 may be formed of a dielectric material that is coated, covered, encapsulated, or the like with a metal layer. The ultrasonic elements 104 are configured to change dimensions upon application of an energizing signal, such as a voltage. The ultrasonic elements 104 may be excited by energizing signals, such as a resonant frequency AC signals. As the energizing signals are applied to the ultrasonic elements 104, the ultrasonic elements 104 change shape, and thereby emit ultrasonic signals.

As shown in FIG. 1, the ultrasonic elements 104 may be positioned at different heights by a pedestal 116 that is supported on the top surface 110 of the substrate 102. However, the ultrasonic elements 104 may be directly supported on the top surface 110 so as to be coplanar. The assembly 100 may include more or less ultrasonic elements 104 than shown.

The cover 106 includes perimeter walls 118 integrally connected to a covering wall 120 that may be orthogonal to the perimeter walls 118. Base edges 122 of the perimeter walls 118 are securely mounted to the top surface 110 of the substrate 102. For example, the base edges 122 may be hermetically sealed to the top surface 110. As shown, the cover 106 may provide a box-like structure over the substrate 102. The cover 106 defines an internal chamber 124 between internal surfaces of the perimeter walls 118, internal surfaces of the covering wall 120, and the top surface 110 of the substrate 102. The array of ultrasonic elements 104 is secured within the internal chamber 124. As shown, wire bond pads 114 bound (for example, are positioned outside of) a perimeter of the cover.

The cover 106 may be formed of an ultrasonically-transparent material. For example, the cover 106 may be formed of plastic, aluminum oxide, and/or the like.

The cover 106 supports and/or routes a plurality of wires 130. Each ultrasonic element 104 connects to a separate and distinct wire bond pad 114 through a separate and distinct wire 130. For example, an array that includes a total of 25 separate and distinct ultrasonic elements 104 connects each of the ultrasonic elements 104 to 25 separate and distinct wire bond pads 114 through 25 separate and distinct wires 130.

Each wire 130 may include a tail 132 that may be wire bonded to a wire bond pad 114. The tail 132 integrally connects to a perimeter wall extension segment 134 that extends over an outer portion of a perimeter wall 118. The perimeter wall extension segment 134, in turn, integrally connects to a spanning segment 136 that spans over the covering wall 120. The spanning segment 136 integrally connects to a connecting segment 138 that passes through a channel formed through the covering wall 120 over a particular ultrasonic element 104. The connecting segment 138 may sealingly engage the covering wall 120 through the channel. As shown, the connecting segment 138 may be parallel with the extension segment 134. The connecting segment 138 may, in turn, integrally connect to a contact segment 140, which may be orthogonal to the connecting segment 138. The contact segment 140 may directly abut into a surface of a particular ultrasonic element 104. For example, the contact segment 140 may be spring-biased into the particular ultrasonic element 104. Optionally, the contact segment 140 may be wire bonded to the particular ultrasonic element 104.

The assembly 100 is configured to provide independent electrical connections to each individual ultrasonic element 104. The cover 106 supports and directs the wires 130 to respective individual ultrasonic elements 104. Accordingly, an electrical path is established between each ultrasonic element 104 through a respective wire 130 that connects to a separate and distinct wire bond pad 114. Accordingly, an electrical or energizing signal may pass from a driver, circuit board, and/or the like, through a pin extending from the bottom surface 112 of the substrate 102, into a wire bond pad 114, and to a particular ultrasonic element 104 through a wire 130. Each wire 130 contacts a single ultrasonic element 104 and terminates at a single wire bond pad 114.

As shown, the majority of each wire 130 may be vertically oriented. The majority of each wire 130 may be oriented along a direction that is normal to the plane of the top surface 110 of the substrate 102. For example, the majority of the length of each wire 130 is defined by the perimeter wall extension segment 134 and the connecting segment 138, which are parallel to one another, and orthogonal to the top surface 110 of the substrate 102. It has been found that the substantial vertical orientation of the wires 130 in relation to the substrate 102 (as shown in FIG. 1) provides structures that are generally transparent to incident ultrasonic energy emitted from the ultrasonic elements 104.

As noted above, the contacting segments 140 of the wires 130 may be spring-biased into top surfaces of respective ultrasonic elements 104. Bonding of the contacting segments 140 to the ultrasonic elements 104 may be strengthened by coating the ultrasonic elements with one or more materials that scrub clean under the motion of the ultrasonic elements. For example, the coating may be formed of gold or other soft metals. Additionally, at least portions of the segments 134, 136, and 138 (such as the portion of the segment 138 that extends through the covering wall 120) may be bonded to the cover 106, such as through brazing (such as if the cover 106 is formed of a ceramic material), sealants (such as if the cover 106 is formed of a plastic), and/or the like.

FIG. 2 illustrates a perspective top view of an ultrasonic sensor array assembly 200, according to an embodiment of the present disclosure. The assembly 200 is similar to the assembly 100, except that a cover 202 is disposed outside of wire bond pads 204. The perimeter walls of the cover 202 bound (for example, are disposed outside of) the wire bond pads 204. In this embodiment, the cover 202 may be formed of a ceramic material and bonded, such as through brazing, to a metal ring 206 (such as formed of gold) that is exposed through and/or extends from a top surface 208 of a substrate 210. As such, wires 212 may be contained within an internal chamber 213 and connect to internal wall portions of the cover 202. Each wire 212 may contact a respective ultrasonic element 214 and connect to a respective wire bond pad 204.

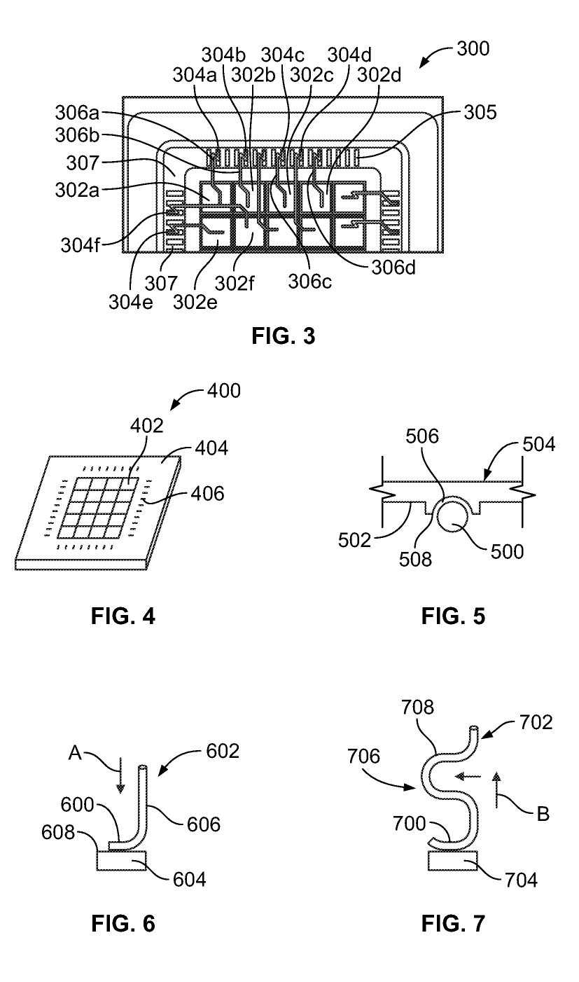

FIG. 3 illustrates a top view of a portion of an ultrasonic sensor array assembly 300, according to an embodiment of the present disclosure. For the sake of clarity, a cover is not shown in FIG. 3. As shown, each ultrasonic element may be independently electrically connected to a wire bond pad through a separate and distinct wire. For example, the ultrasonic elements 302a, 302b, 302c, and 302d connect to separate and distinct wire bond pads 304a, 304b, 304c, and 304d, respectively, within a pad row 305, through separate and distinct wires 306a, 306b, 306c, and 306d, respectively. Ultrasonic elements 302e and 302f connect to separate and distinct wire bond pads 304e and 304f, respectively, with in a pad column 307, through separate and distinct wires 306e and 306f, respectively. Each ultrasonic element connects to a separate and distinct wire bond pad through a separate and distinct wire. The ultrasonic sensor array assembly 300 may include more or less ultrasonic elements, wire bond pads, and wires than shown.

FIG. 4 illustrates a perspective top view of a substrate 400, according to an embodiment of the present disclosure. As shown, the substrate 400 supports an array of ultrasonic elements 402. All of the ultrasonic elements 402 may reside within a single plane, which may be parallel to a plane defined by a top surface 404 of the substrate 400. Each of the ultrasonic elements 402 may connect to a separate and distinct wire bond pad 406 through a separate and distinct wire, as described above.

FIG. 5 illustrates an axial view of a wire segment 500 positioned on an internal wall 502 portion of a cover 504, according to an embodiment of the present disclosure. A wire channel 506, such as a trough, groove, or the like, may be formed through or extend from or within the internal wall 502. The wire channels 506 may be defined by a cradling track 508 that receives and retains the wire segment 500 within the wire channel 506. The cradling track 508 may cradle the wire segment 500. In at least one embodiment, the cradling track 508 may securely retain the wire segment 500 through an interference fit. In at least one other embodiment, the wire segment may be adhesively secured within the wire channel 506.

While shown on the internal wall 502, the wire channel 506 may alternatively be formed on or within an external or outer wall portion or surface of the cover 504. As such, the wire segment 500 may be positioned on an outer surface of the cover 504.

The wire segment 500 may be any portion of a wire that contacts a wall portion of the cover 504. The wall portion 504 may be a perimeter or covering wall.

FIG. 6 illustrates a lateral view of a contact segment 600 of a wire 602 contacting an ultrasonic element 604, according to an embodiment of the present disclosure. As shown, the contact segment 600 may be a spring-biased portion of the wire 602. For example, the contact segment 600 may be an out-turned foot of the wire 602 that is outwardly bent with respect to a connecting segment 606. The connecting segment 606 exerts a force A into the contact segment 600 that forces the contact segment 600 to exert a spring-biased force into a top surface 608 of the ultrasonic element 604. As such, the contact segment 600 is compressed into the ultrasonic element 604, thereby providing an electrical connection therewith.

FIG. 7 illustrates a lateral view of a contact segment 700 of a wire 702 contacting an ultrasonic element 704, according to an embodiment of the present disclosure. The contact segment 700 connects to a connecting segment 706 that includes a spring beam portion 708, such as bent, kinked, looped, or bowed portion. The bend of the spring beam portion 708 prevents ultrasonic energy emitted by the ultrasonic element 704 from propagating up the wire 702 in the direction of arrow B. Additionally, the spring beam portion 708 may provide an additional force-exerting member that increases the contact force exerted by the contact segment 700 into the ultrasonic element 704.

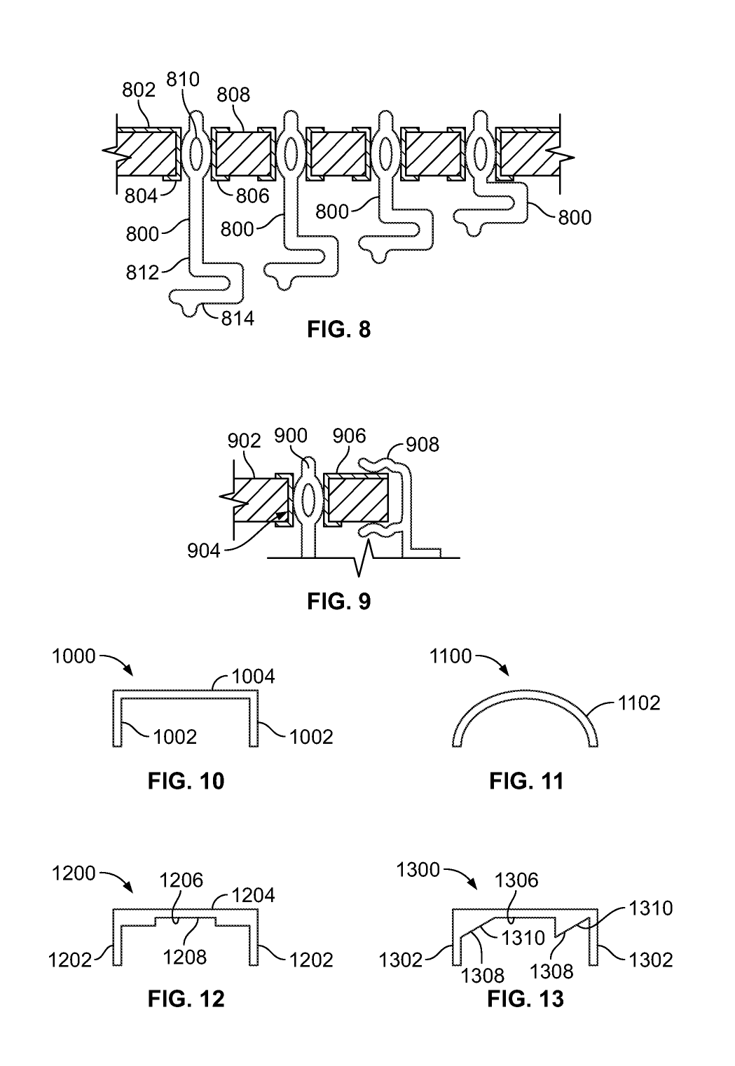

FIG. 8 illustrates a transverse cross-sectional view of wires 800 secured to a portion of a cover 802, according to an embodiment of the present disclosure. The portion of the cover 802 may be a covering wall, for example. The cover 802 may include a plurality of channels 804 formed therethrough. A conductive via 806 may be securely retained within each channel 804. Each via 806 may connect to circuit board material 808, such as one or more traces, that electrically connect to a wire bond pad (not shown in FIG. 8).

Each wire 800 may include a via-contact segment 810, such as an eye-of-the-needle contact, that contacts a respective via 806. The via-contact segment 810 connects to a connecting segment 812, which, in turn, connects to a contact segment 814, which is configured to contact a respective ultrasonic element, as described above. As such, the wire 800 may not extend around or in an entire length of a wall portion of the cover 802. Instead, the wire 800 may connect to a via 806, which connects to a wire bond pad through circuit board material 808.

FIG. 9 illustrates a transverse cross-sectional view of a wire 900 secured to a portion of a cover 902, according to an embodiment of the present disclosure. The wire 900 is similar to the wires 800 described with respect to FIG. 8. A via 904 may connect to a trace 906. A clamping contact 908 may electrically connect the trace 906 to a wire bond pad.

FIG. 10 illustrates a transverse cross-sectional view of a cover 1000, according to an embodiment of the present disclosure. The cover 1000 includes perimeter walls 1002 connected to a covering wall 1004, thereby providing a box-like structure.

FIG. 11 illustrates a transverse cross-sectional view of a cover 1100, according to an embodiment of the present disclosure. The cover 1100 includes a hemispherical wall 1102 that provides a dome-like structure.

FIG. 12 illustrates a transverse cross-sectional view of a cover 1200, according to an embodiment of the present disclosure. The cover 1200 includes perimeter walls 1202 connected to a covering wall 1204. An internal surface 1206 of the covering wall 1204 may include one or more prismatic elements 1208, such as geometric shapes formed therein. For example, the prismatic element 1208 shown in FIG. 12 may be or include a rectangular channel formed through the internal surface 1206. The prismatic element 1208 is configured to modify the shape of the ultrasonic beam emitted from an array of ultrasonic elements. The thickness and shape of the covering wall 1204 may be selectively modified to provide a lens that focuses a beam of a desired shape and size.

FIG. 13 illustrates a transverse cross-sectional view of a cover 1300, according to an embodiment of the present disclosure. The cover 1300 includes perimeter walls 1302 connected to a covering wall 1304. An internal surface 1306 of the covering wall 1304 may include prismatic elements 1308, such as geometric shapes formed therein. The prismatic elements 1308 may include angled or ramped surfaces 1310. Various other shapes and sizes may be used. For example, the prismatic elements 1308 may be or include concave or convex surfaces, irregularly-shaped surfaces, and/or the like. The prismatic elements 1308 may be or include tapered surfaces, facets, grooves, ridges, and/or the like.

Referring to FIGS. 12 and 13, the prismatic elements are configured to refract sound. The prismatic elements provide acoustic lenses that shape, distort, and/or otherwise form (at least in part) ultrasonic energy emitted from ultrasonic elements.

Referring to FIGS. 1-13, embodiments of the present disclosure provide ultrasonic sensor array assemblies that are configured to efficiently electrically phase individual transducer or ultrasonic elements. Each ultrasonic element is connected to a separate and distinct contact pad (such as a wire bond pad) through a separate and distinct wire.

Embodiments of the present disclosure provide ultrasonic sensor array assemblies that may include a plurality of individual ultrasonic elements that are independently electrically connected to one or more contact pads, which are, in turn, electrically connected to a source of energy. Because each ultrasonic element is electrically independent from one another, the ultrasonic sensor array assembly is able to form an ultrasonic beam through electronic phasing.

While various spatial terms, such as upper, bottom, lower, mid, lateral, horizontal, vertical, and the like may be used to describe embodiments of the present disclosure, it is understood that such terms are merely used with respect to the orientations shown in the drawings. The orientations may be inverted, rotated, or otherwise changed, such that an upper portion is a lower portion, and vice versa, horizontal becomes vertical, and the like.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the disclosure without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the disclosure should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means—plus-function format and are not intended to be interpreted based on 35 U.S.C. § 112(f), unless and until such claim limitations expressly use the phrase “means for” followed by a statement of function void of further structure.

What is claimed is:

1. An ultrasonic sensor array assembly, comprising:
a substrate having a plurality of contact pads; and
a plurality of ultrasonic elements supported on the substrate, wherein each of the plurality of ultrasonic elements is independently electrically connected to a respective one of the plurality of contact pads, and wherein the plurality of ultrasonic elements are configured to emit an electrically phased ultrasonic beam.

2. The ultrasonic sensor array assembly of claim 1, further comprising a cover positioned over the plurality of ultrasonic elements.

3. The ultrasonic sensor array assembly of claim 2, wherein the plurality of contact pads bound a perimeter of the cover.

4. The ultrasonic sensor array assembly of claim 2, wherein perimeter walls of the cover bound the plurality of contact pads.

5. The ultrasonic sensor array assembly of claim 1, further comprising a plurality of wires, wherein each of the plurality of ultrasonic elements connects to a respective one of the contact pads through a respective one of the plurality of wires.

6. The ultrasonic sensor array assembly of claim 5, wherein each of the plurality of wires includes a contact segment that is spring-biased into a respective one of the plurality of ultrasonic elements.

7. The ultrasonic energy array assembly of claim 5, wherein each of the plurality of wires includes a bent spring beam portion.

8. The ultrasonic sensor array assembly of claim 5, further comprising a cover positioned over the plurality of ultrasonic elements, wherein at least portions of the plurality of wires extend over internal or external wall portions of the cover.

9. The ultrasonic sensor array assembly of claim 8, wherein the at least portions of the plurality of wires are cradled within one or more channels formed through the cover.

10. The ultrasonic energy array assembly of claim 8, wherein each of the plurality of wires includes a via-contacting portion retained within a via that is secured within the cover.

11. The ultrasonic sensor array assembly of claim 1, wherein the plurality of ultrasonic elements are coplanar.

12. The ultrasonic sensor array assembly of claim 1, wherein the cover includes one or more prismatic elements that are configured to shape the electrically phased ultrasonic beam that is emitted from the plurality of ultrasonic elements.

13. An ultrasonic sensor array assembly, comprising:
a substrate having a plurality of contact pads;
a plurality of ultrasonic elements supported on the substrate, wherein each of the plurality of ultrasonic elements is independently electrically connected to a respective one of the plurality of contact pads, and wherein the plurality of ultrasonic elements are configured to emit an electrically phased ultrasonic beam;
a cover positioned over the plurality of ultrasonic elements; and
a plurality of wires, wherein each of the plurality of ultrasonic elements connects to a respective one of the contact pads through a respective one of the plurality of wires, wherein at least portions of the plurality of wires extend over internal or external wall portions of the cover.

14. The ultrasonic sensor array assembly of claim 13, wherein the plurality of contact pads bound a perimeter of the cover.

15. The ultrasonic sensor array assembly of claim 13, wherein perimeter walls of the cover bound the plurality of contact pads.

16. The ultrasonic sensor array assembly of claim 13, wherein each of the plurality of wires includes a contact segment that is spring-biased into a respective one of the plurality of ultrasonic elements.

17. The ultrasonic energy array assembly of claim 13, wherein each of the plurality of wires includes a bent spring beam portion.

18. The ultrasonic sensor array assembly of claim 13, wherein the at least portions of the plurality of wires are cradled within one or more channels formed through the cover.

19. The ultrasonic energy array assembly of claim 13, wherein each of the plurality of wires includes a via-contacting portion retained within a via that is secured within the cover.

20. The ultrasonic sensor array assembly of claim 13, wherein the cover includes one or more prismatic elements that are configured to shape the electrically phased ultrasonic beam that is emitted from the plurality of ultrasonic elements.
